(19) United States
(12) Patent Application Publication
(10) Pub. No.: US 2026/0304827 A1
(43) Pub. Date: Oct. 1, 2026

(54) GERMANIUM LAYER FOR POWER MOSFET

(71) Applicant: Microchip Technology Incorporated, Chandler, AZ (US)

(72) Inventor: Shesh Mani Pandey, Gilbert, AZ (US)

(73) Assignee: Microchip Technology Incorporated, Chandler, AZ (US)

(21) Appl. No.: 19/441,274

(22) Filed: Jan. 6, 2026

Related U.S. Application Data
(60) Provisional application No. 63/778,633, filed on Mar. 27, 2025.

(51) Int. Cl. H10D 30/66; H10D 30/01; H10D 62/10; H10D 62/832; H10D 64/27; H10D 64/68

(52) U.S. Cl. CPC H10D 30/66; H10D 30/0291; H10D 62/106; H10D 64/516; H10D 62/8325; H10D 64/691

(57) ABSTRACT

A MOSFET comprises an epitaxial region, a JFET neck region of the epitaxial region, a gate, and a germanium layer of the epitaxial region. The epitaxial region includes a top, an opposite bottom spaced vertically from the top, a first side, and a laterally opposite second side spaced from the first side. The JFET neck region is between the first and second sides. The gate is adjacent the top. The JFET neck region underlies at least a portion of the gate. The germanium layer is adjacent the top and underlies at least a portion of the gate.

### CROSS-REFERENCE TO RELATED APPLICATIONS

The current patent application claims the benefit under 35 U.S.C. § 119(e) of the priority date of U.S. Provisional Application Ser. No. 63/778,633; titled “GERMANIUM IMPLANT TO IMPROVE SIC POWER MOSFET PERFORMANCE”; and filed Mar. 27, 2025. The Provisional Application is hereby incorporated by reference, in its entirety, into the current patent application.

### TECHNICAL FIELD

The present disclosure relates to metal-oxide semiconductor field-effect transistors.

### BACKGROUND

A metal-oxide semiconductor field-effect transistor (MOSFET) is an active, voltage-controlled semiconductor device, in which varying an electrical voltage between a gate and a source controls an electrical current flowing through a semiconductor channel between a drain and the source. Applications for MOSFETs include amplifiers, switches, resistors, regulators, oscillators, and choppers. It is generally desirable to improve the performance and reduce the cost of MOSFETs, but it can be difficult to do so.

This background discussion is intended to provide related information, and is not necessarily prior art.

### SUMMARY OF THE INVENTION

In various examples of the present disclosure, a MOSFET comprises an epitaxial region, a junction field effect transistor (JFET) neck region of the epitaxial region, a gate, and a germanium layer of the epitaxial region. The epitaxial region includes a top, an opposite bottom spaced vertically from the top, a first side, and a laterally opposite second side spaced from the first side. The JFET neck region is between the first and second sides. The gate is adjacent the top. The JFET neck region underlies at least a portion of the gate. The germanium layer is adjacent the top and underlies at least a portion of the gate.

In various examples of the present disclosure, a MOSFET comprises an epitaxial region, a JFET neck region of the epitaxial region, a gate, and a germanium layer of the epitaxial region. The epitaxial region includes a top, an opposite bottom spaced vertically from the top, a first side, and a laterally opposite second side spaced from the first side. The JFET neck region is between the first and second sides. The gate is adjacent the top. The gate includes a gate dielectric. The gate dielectric includes a central thickened dielectric portion having a greater thickness than outer remaining portions of the gate dielectric. The JFET neck region underlies the central thickened dielectric portion. The germanium layer is adjacent the top and extends laterally across an upper portion of the JFET neck region.

In various examples of the present disclosure, a method of making a MOSFET using an epitaxial region on a drain substrate is provided. The epitaxial region includes a top, an opposite bottom spaced vertically from the top, a first side, a laterally opposite second side spaced from the first side, and a JFET neck region adjacent the top between the first and second sides. The method comprises: forming laterally spaced first and second wells of the epitaxial region adjacent the top, the first and second wells forming respective innermost junctions with the JFET neck region, the JFET neck region extending between the respective innermost junctions; forming a germanium layer of the epitaxial region adjacent the top, the germanium layer extending continuously between the respective innermost junctions; and forming a gate adjacent the top, the gate comprising a gate dielectric.

This summary is not intended to identify essential features of the examples, and is not intended to be used to limit the scope of the claims. These and other aspects of the present examples are described below in greater detail.

### BRIEF DESCRIPTION OF THE DRAWINGS

FIG. 1 illustrates a cross-sectional elevation view of an example MOSFET having a germanium layer in accordance with examples of the present disclosure;

FIG. 2 illustrates a cross-sectional elevation view of an example MOSFET having a germanium layer and a thickened oxide layer in accordance with examples of the present disclosure;

FIG. 3 illustrates a cross-sectional elevation view of an example MOSFET having a germanium layer within a junction field effect transistor (JFET) neck region of a volume of semiconductor material and a thickened oxide layer in accordance with examples of the present disclosure;

FIG. 4 illustrates a cross-sectional elevation view of an example MOSFET following formation of a germanium layer within a JFET neck region of a volume of semiconductor material in accordance with examples of the present disclosure; and

FIG. 5 illustrates a method for manufacturing a MOSFET having a germanium layer in accordance with examples of the present disclosure.

Unless otherwise indicated, the figures provided herein are meant to illustrate features of examples of this disclosure. These features are believed to be applicable in a wide variety of systems comprising one or more examples of this disclosure. As such, the figures are not meant to include all conventional features known by those of ordinary skill in the art to be required for the practice of the examples disclosed herein.

### DETAILED DESCRIPTION

In the following detailed description, reference is made to the accompanying drawings, which form a part hereof and in which are shown, by way of illustration, specific examples in which the present disclosure may be practiced. These examples are described in sufficient detail to enable a person of ordinary skill in the art to practice the present disclosure. However, other examples may be utilized, and structural, material, procedural, operational, and other changes may be made without departing from the scope of the disclosure. Unless clearly understood or expressly identified otherwise, structures, materials, procedures, operations, and other aspects described in the context of one example may be incorporated into other examples.

The illustrations presented herein are not meant to be actual views of any particular method, system, device, or structure, but are merely idealized representations that are employed to describe the examples of the present disclosure. The drawings presented herein are not necessarily drawn to scale. Similar structures or components in the various drawings may retain the same or similar numbering for the convenience of the reader; however, any similarity in numbering does not necessarily mean that the structures or components are necessarily identical in size, composition, configuration, or any other property.

Terms of relative location and direction (e.g., above, below, left, right, upper, lower, vertical, horizontal (or lateral)) may be used to facilitate the present descriptions of examples with reference to the figures, but unless clearly understood or expressly identified otherwise, these terms are not meant to be limiting with regard to location, direction, or overall orientation, and may, for example, change as a result of a change in overall orientation.

Thus, it will be readily understood that the components of the examples as generally described herein and illustrated in the drawings could be arranged and designed in a wide variety of different configurations. Thus, the following description of various examples is not intended to limit the scope of the present disclosure but is merely representative of various examples.

Examples provide a metal-oxide field effect transistor (MOSFET). The example MOSFET may be suitable for very high-voltage applications, and may operate at a voltage greater than one thousand (1,000) Volts (V). More specifically, the example MOSFET may be rated for a voltage of around twelve hundred three thousand three hundred (3,300) V or greater. It would be appreciated by one of ordinary skill in the art that the example MOSFET may be suitable for lower voltage applications without departing from the scope of the present disclosure.

The example MOSFET may include a volume of semiconductor material comprising a drain substrate and an epitaxial region. The epitaxial region may be epitaxially grown on the drain substrate. The epitaxial region has a top and an opposite bottom vertically spaced from the top, a first side and an opposite second side laterally spaced from the first side. The volume of semiconductor material may be formed of silicon carbide (SiC). A germanium layer may be formed within the epitaxial region adjacent the top. The epitaxial region may additionally include a junction field effect transistor (JFET) neck region. The germanium layer may extend at least across the JFET neck region adjacent the top. A gate may be placed adjacent and above the top. The gate may include a doped gate material and a gate dielectric. The gate dielectric may be formed through an oxidation process in which oxygen interacts with germanium particles of the germanium layer and silicon particles of the epitaxial region such that the gate dielectric comprises both germanium dioxide (GeO2) and silicon dioxide (SiO2). In various examples, the gate dielectric may have a thickened portion in an area axially aligned with the JFET neck region along a vertical axis (e.g., thickened as compared to outer portions of the gate dielectric that are not axially aligned with the JFET neck region).

In various examples, the addition of the germanium layer may provide a smooth interface between the gate dielectric and the underlying semiconductor material, thereby reducing a drain-source on resistance (Rdson). Further, an amount of time needed to form the gate dielectric may be reduced due to the oxidation of the germanium particles of the germanium layer in addition to oxidation of silicon particles of the epitaxial region. Moreover, the thickened gate dielectric over the JFET neck region may reduce a gate-to-drain capacitance of the example MOSFET and may shield the gate from an electric field projecting from the drain substrate, thereby improving device longevity and overall performance.

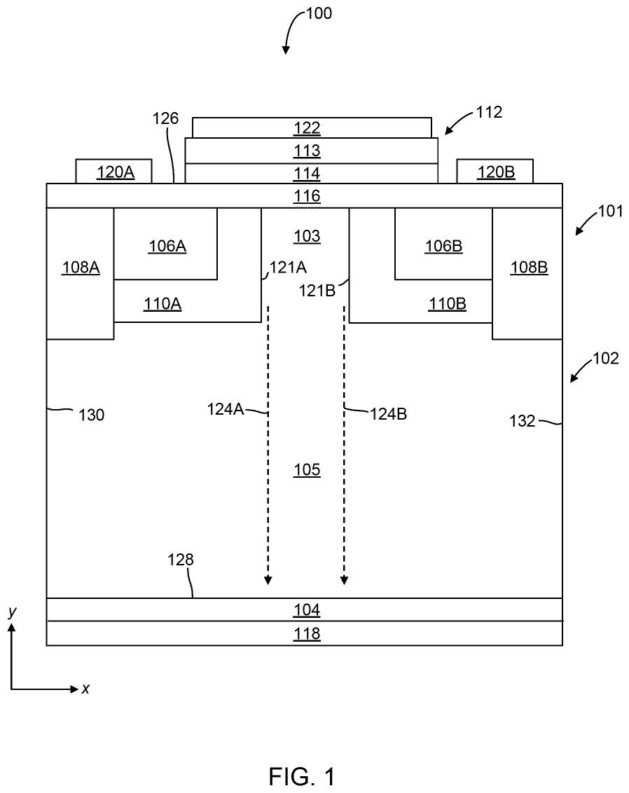

Referring to FIG. 1, an example MOSFET 100 is shown. The MOSFET 100 includes a volume of semiconductor material 101, a gate 112, a germanium layer 116, a drain contact 118, and source contacts 120A, 120B. The volume of semiconductor material 101 includes an epitaxial region 102 and a drain 104. The epitaxial region 102 includes a top 126, an opposite bottom 128 vertically spaced along a vertical axis (e.g., the y axis shown in FIG. 1) from the top 126, a first side 130, and a second side 132 laterally opposite the and spaced from the first side 130 along a horizontal axis (e.g. the x axis shown in FIG. 1) perpendicular to the y axis. The epitaxial region 102 additionally includes a JFET neck region 103, a drift region 105, a first source 106A, a second source 106B, a first P+ doped well region 108A, a second P+ doped well region 108B, a first P doped well region 110A, and a second P doped well region 110B. The drain 104 is located adjacent the bottom 128. The gate 112 is located adjacent the top 126.

The epitaxial region 102 may be epitaxially grown or otherwise formed on the drain 104. The drain 104 may comprise an N+ doped drain substrate. The epitaxial region 102 may be initially formed as an N doped epitaxial semiconductor material and may be modified by introduction of additional dopants (e.g., to form the sources 106A, 106B, P+ doped well regions 108A, 108B, and P doped well regions 110A, 110B).

In various examples, the sources 106A, 106B, the drift region 105, the JFET neck region 103, and drain 104 may have a first charge carrier polarity (e.g., negative). The drift region 105 and the JFET neck region 103 may include an N doped epitaxial material. The drain contact 118 may underlie the drain 104. The P doped well regions 110A, 110B and the P+ doped well regions 108A, 108B may have a second charge carrier polarity (e.g., positive).

Each of the first and second sources 106A, 106B may include an N+ dopant deposited (e.g., via ion implantation) into or otherwise formed within the epitaxial region 102 adjacent the top 126. The first source 106A may be located adjacent the P+ doped well region 108A and the P doped well region 110A. At least a portion of the first source 106A and a portion of the first P doped well region 110A may underlie the gate 112. The second source 106B may be located adjacent the P+ doped well region 108B and the P doped well region 110B. At least a portion of the second source 106B and a portion of the second P doped well region 110B may underlie the gate 112. The first source contact 120A is placed on the top 126 adjacent the first source 106A. A portion of the first P+ doped well region 108A may underlie the first source contact 120A. The second source contact 120B is placed on the top 126 adjacent the second source 106B. A portion of the second P+ doped well region 108B may underlie the second source contact 120B.

The first and second P+ doped well regions 108A, 108B may include a P+ dopant deposited (e.g., via ion implantation) into or otherwise formed into the epitaxial region 102 adjacent the top 126. The first P+ doped well region 108A may be deposited adjacent the first side 130. The second P+ doped well region 108B may be deposited adjacent the second side 132. The first P+ doped well region 108A may extend laterally between the first side 130 and the first source 106A. The second P+ doped well region 108B may extend laterally between the second side 132 and the second source 106B.

The first and second P doped well regions 110A, 110B may include a P dopant deposited (e.g., via ion implantation) into or otherwise formed into the epitaxial region 102 adjacent the top 126. A first portion of the first P doped well region 110A may extend laterally between the first source 106A and the JFET neck region 103. A second portion of the first P doped well region 110A may extend laterally between the first P+ doped well region 108A and the JFET neck region 103. The first portion of the P doped well region 110A may extend from the top 126 and underlie the gate 112. The second portion of the P doped well region 110A may at least partially underlie the first source 106A. The first P doped well region 110A may form a first innermost junction 121A with the JFET neck region 103. A first portion of the second P doped well region 110B may extend laterally between the second source 106B and the JFET neck region 103. A second portion of the second P doped well region 110B may extend laterally between the second P+ doped well region 108B and the JFET neck region 103. The first portion of the P doped well region 110B may extend from the top 126 and underlie the gate 112. The second portion of the P doped well region 110B may at least partially underlie the second source 106B. The second P doped well region 110B may form a second innermost junction 121B with the JFET neck region 103.

The gate 112 is located adjacent the top 126 and includes a doped gate material 113, a gate dielectric 114, and a gate contact 122. The gate dielectric 114 may underlie the doped gate material 113 and may have a uniform thickness (e.g., along the y axis).

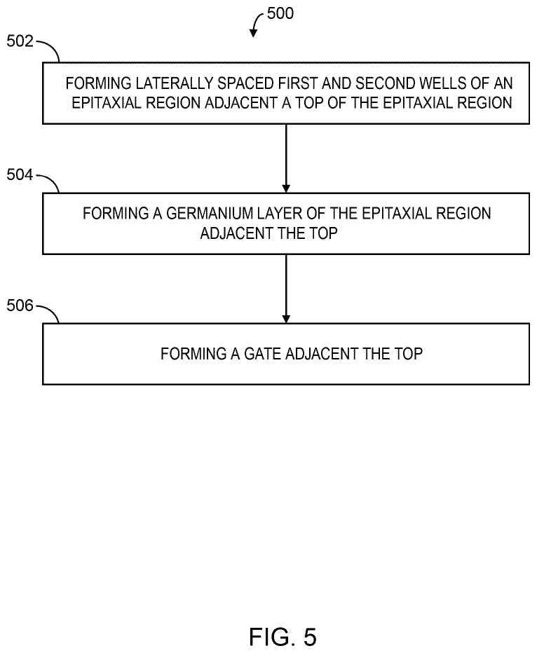

The gate dielectric 114 may include or comprise an oxide, such as silicon dioxide (SiO2) and/or germanium dioxide (GeO2). The gate dielectric 114 may be formed by an oxidation process, which is described in greater detail below and in connection with the method 500 of FIG. 5. The doped gate material 113 may include doped polysilicon.

During operation, a voltage applied to the gate contact 122 may form channels 124A, 124B through which charge carriers move in a flow of electrical energy between the first and second sources 106A, 106B on the one hand and the drain 104 on the other hand. It will be understood by one of ordinary skill in the art that the dashed lines representing the channels 124A, 124B are merely representative and charge carriers moving through the channels 124A, 124B do not necessarily follow a straight line.

The germanium layer 116 may extend laterally across an upper portion of the JFET neck region 103 (e.g., adjacent the top 126). More particularly, the germanium layer 116 may extend continuously between the first side 130 and the second side 132. The germanium layer 116 may be deposited (e.g., implanted) or otherwise formed within the epitaxial region 102 adjacent the top 126. Accordingly, the sources 106A, 106B, P+ doped well regions 108A, 108B, and P doped well regions 110A, 110B may include respective portions of the germanium layer 116 adjacent the top 126.

During formation of the gate dielectric 114, germanium particles of the germanium layer 116 may become oxidized, thereby forming a GeO2 portion of the gate dielectric 114. Silicon particles of the epitaxial region 102 may become oxidized to form a SiO2 portion of the gate dielectric 114. Accordingly, the gate dielectric 114 may include both GeO2 and SiO2.

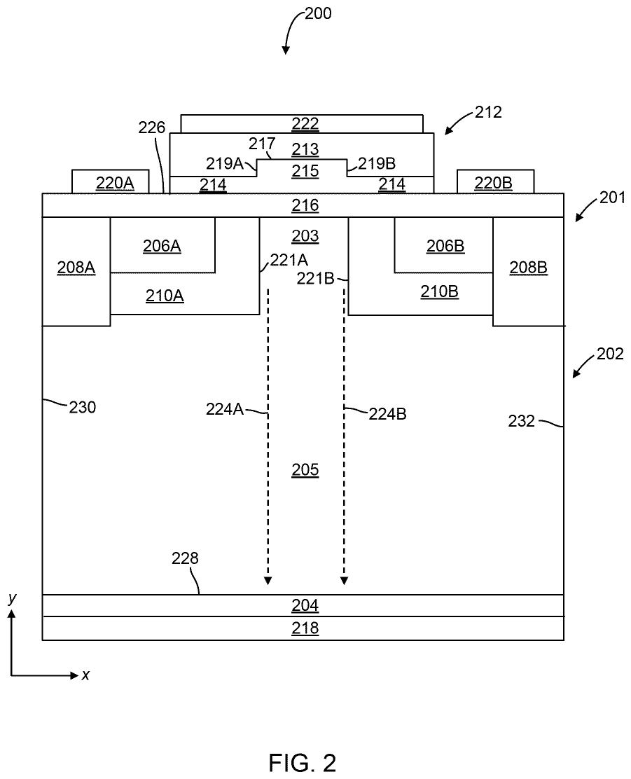

Referring to FIG. 2, an example MOSFET 200 is shown. The MOSFET 200 includes a volume of semiconductor material 201, a gate 212, a germanium layer 216, a drain contact 218, and source contacts 220A, 220B. The volume of semiconductor material 201 includes an epitaxial region 202 and a drain 204. The epitaxial region 202 includes a top 226, an opposite bottom 228 spaced along a vertical axis (e.g., the y axis shown in FIG. 2) from the top 226, a first side 230, and a second side 232 laterally opposite and spaced from the first side 230 along a horizontal axis (e.g. the x axis shown in FIG. 2) perpendicular to the y axis. The epitaxial region 202 additionally includes a JFET neck region 203, a drift region 205, a first source 206A, a second source 206B, a first P+ doped well region 208A, a second P+ doped well region 208B, a first P doped well region 210A, and a second P doped well region 210B. The drain 204 is located adjacent the bottom 228.

The gate 212 is located adjacent the top 226 and includes a doped gate material 213, a gate dielectric 214, and a gate contact 222. The doped gate material 213 and the gate dielectric 214 may respectively comprise the same materials described in connection with the doped gate material 113 and the gate dielectric 114 of FIG. 1.

During operation, a voltage applied to the gate contact 222 may form channels 224A, 224B though which charge carriers may move in a flow of electrical energy between the first and second sources 206A, 206B on the one hand and the drain 204 on the other hand. It will be understood by one of ordinary skill in the art that the dashed lines representing the channels 224A, 224B are merely representative and charge carriers moving through the channels 224A, 224B do not necessarily follow a straight line.

The first P doped well region 210A may form a first innermost junction 221A with the JFET neck region 203. The second P doped well region 210B may form a second innermost junction 221B with the JFET neck region 203.

In various examples, doped regions of the volume of semiconductor material 201 (e.g., the JFET neck region 203, drain 204, drift region 205, sources 206A, 206B, P+ doped well regions 208A, 208B, and P doped well regions 210A, 210B) may respectively be identical to or substantially the same as the analogous doped regions of the volume of semiconductor material 101 of FIG. 1 and are not described again for brevity. Similarly, the drain contact 218, source contacts 220A, 220B, and the gate contact 222 may respectively be identical to or substantially the same as the analogous drain contact 118, source contacts 120A, 120B, and gate contact 122 of FIG. 1 and are not described again for brevity.

The gate dielectric 214 includes a central thickened dielectric portion 215. The central thickened dielectric portion 215 may form an uppermost junction 217 and outermost junctions 219A, 219B with the doped gate material 213. The central thickened dielectric portion 215 may extend continuously between the outermost junctions 219A, 219B. In various examples, the doped gate material 213 may present a recess for receiving the thickened portion 215. The recess may be bounded by the uppermost junction 217 and the outermost junctions 219A, 219B. The thickened portion 215 may have a larger thickness (e.g., along the y axis) than remaining outer portions of the gate dielectric 214 (e.g., portions of the gate dielectric 214 located laterally outside of the bounds of the recess). The thickened portion 215 may be at least ten percent (10%), at least twenty-five percent (25%), at least fifty percent (50%), or at least one hundred percent (100%) thicker than the remaining outer portions of the gate dielectric 214. In various examples, the doped gate material 213 may be formed around the thickened portion 215 to form the junctions 217, 219A, 219B.

In various examples, the thickened portion 215 may be aligned axially with the JFET neck region 203 (e.g. along the y axis). Accordingly, the outermost junction 219A may be axially aligned with the innermost junction 221A, and the outermost junction 219B may be axially aligned with the innermost junction 221B. The thickened portion 215 may have a lateral width (e.g., along the x axis) equal to a lateral width (e.g., along the x axis) of the JFET neck region 203. The lateral width of the JFET neck region 203 may be defined by a lateral distance (e.g., along the x axis) between the first and second innermost junctions 221A, 221B. In various examples, the innermost junctions 221A, 221B and outermost junctions 219A, 219B may not be axially aligned without departing from the scope of the present disclosure.

In various examples, the germanium layer 216 may be identical to or substantially the same as the germanium layer 116 of FIG. 1 and is not described again for brevity.

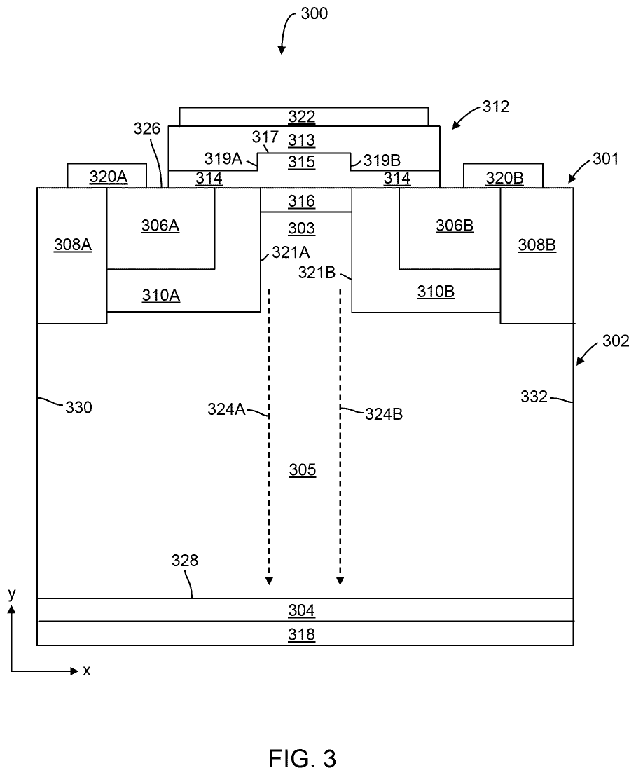

Referring to FIG. 3, an example MOSFET 300 is shown. The MOSFET 300 includes a volume of semiconductor material 301, a gate 312, a germanium layer 316, a drain contact 318, and source contacts 320A, 320B. The volume of semiconductor material 301 includes an epitaxial region 302 and a drain 304. The epitaxial region 302 includes a top 326, an opposite bottom 328 spaced along a vertical axis (e.g., the y axis shown in FIG. 3) from the top 326, a first side 330, and a second side 332 laterally opposite and spaced from the first side 330 along a horizontal axis (e.g. the x axis shown in FIG. 3) perpendicular to the y axis. The epitaxial region 302 additionally includes a JFET neck region 303, a drift region 305, a first source 306A, a second source 306B, a first P+ doped well region 308A, a second P+ doped well region 308B, a first P doped well region 310A, and a second P doped well region 310B. The drain 304 is located adjacent the bottom 328.

The gate 312 is located adjacent the top 326 and includes a doped gate material 313, a gate dielectric 314, and a gate contact 322. The doped gate material 313 and the gate dielectric 314 may respectively comprise the same materials described in connection with the doped gate material 113 and the gate dielectric 114 of FIG. 1.

During operation, a voltage applied to the gate contact 322 may form channels 324A, 324B though which charge carriers may move in a flow of electrical energy between the first and second sources 306A, 306B on the one hand and the drain 304 on the other hand. It will be understood by one of ordinary skill in the art that the dashed lines representing the channels 324A, 324B are merely representative and charge carriers moving through the channels 324A, 324B do not necessarily follow a straight line.

The first P doped well region 310A may form a first innermost junction 321A with the JFET neck region 303. The second P doped well region 310B may form a second innermost junction 321B with the JFET neck region 303.

In various examples, doped regions of the volume of semiconductor material 301 (e.g., the JFET neck region 303, drain 304, drift region 305, sources 306A, 306B, P+ doped well regions 308A, 308B, and P doped well regions 310A, 310B) may be identical to or substantially the same as the analogous doped regions of the volume of semiconductor material 101 of FIG. 1 and are not described again for brevity. Similarly, the drain contact 318, source contacts 320A, 320B, and the gate contact 322 may respectively be identical to or substantially the same as the analogous drain contact 118, source contacts 120A, 120B, and gate contact 122 of FIG. 1 and are not described again for brevity.

The gate dielectric 314 includes a central thickened dielectric portion 315. The central thickened dielectric portion 315 may form an uppermost junction 317 and outermost junctions 319A, 319B with the doped gate material 313. The central thickened dielectric portion 315 may extend continuously between the outermost junctions 319A, 319B. The gate dielectric 314, the thickened dielectric portion 315, and the doped gate material 313, including dimensional and compositional aspects thereof and spatial relationships to other regions of the device 300, may respectively be identical to or substantially the same as the analogous gate dielectric 214, thickened dielectric portion 215, and doped gate material 213 of FIG. 2 and are not described again for brevity.

The germanium layer 316 may extend continuously between and border the first and second innermost junctions 321A, 321B of the P doped well regions 310A, 310B and the JFET neck region 303. The germanium layer 316 may be deposited (e.g., implanted) or otherwise formed within the epitaxial region 302 adjacent the top 326. The germanium layer 316 may extend laterally across an upper portion of the JFET neck region 303 (e.g., adjacent the top 326).

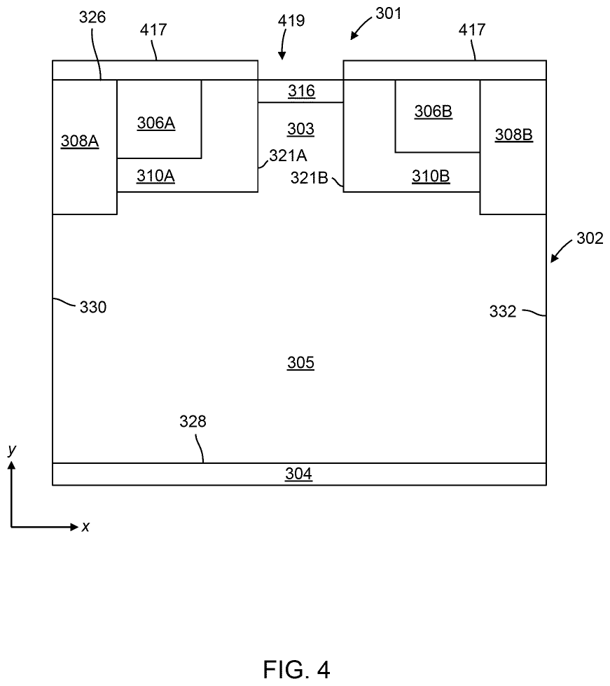

Turning to FIG. 4, the germanium layer 316 may be formed by placing a mask 417 across the top 326. The mask 317 may define a gap 419. In various examples, the mask 317 is axially aligned (e.g., along the y axis) with the JFET neck region 303, such that the gap 419 spans a distance between the innermost junctions 321A, 321B. In other examples, a gap in a mask may be larger or smaller, and/or otherwise misaligned with such innermost junctions, within the scope of the present examples. The germanium layer 316 may be formed within the epitaxial layer 302 through the gap 419. Following formation of the germanium layer 316, the mask 417 may be removed.

It will be appreciated that the example MOSFETs 100, 200, and 300 are N-channel MOSFETs. However, aspects of the example MOSFETs are applicable to P-channel MOSFETs.

Referring to FIG. 5, an example method 500 of manufacturing a MOSFET having a germanium layer, such as the MOSFETs 100, 200, and 300 described above, may include the operations set forth below. The MOSFET may initially include a volume of semiconductor material (e.g., the volumes of semiconductor material 101, 201, 301 of FIGS. 1-3) including an epitaxial region (e.g., the epitaxial regions 102, 202, 302 of FIGS. 1-3) and a drain substrate (e.g., the drains 104, 204, 304 of FIGS. 1-3). The epitaxial region may be epitaxially grown or otherwise formed on the drain substrate. The epitaxial region includes a top (e.g., the tops 126, 226, 326 of FIGS. 1-3), an opposite bottom (e.g., the bottoms 128, 228, 328 of FIGS. 1-3) vertically spaced from the top, a first side (e.g., the first sides 130, 230, 330 of FIGS. 1-3) and a laterally opposite second side (e.g., the second sides 132, 232, 332 of FIGS. 1-3) laterally spaced from the first side. The drain substrate may include an N+ doped substrate material.

At operation 502, the first and second P doped well regions (e.g., the P doped well regions 110A, 110B, 210A, 210B, 310A, 310B of FIGS. 1-3) are formed (e.g., via ion implantation) within the epitaxial region. The first and second P doped well regions may be referred to as first and second wells. The first and second wells may be laterally spaced from each other (e.g., along the x axis). The first and second wells may be formed as part of a dopant formation process in which sources (e.g., the sources 106A, 106B, 206A, 206B, 306A, 306B of FIGS. 1-3) and P+ doped well regions (e.g., the P+ doped well regions 108A, 108B, 208A, 208B, 308A, 308B of FIGS. 1-3) are formed (e.g., via ion implantation) within the epitaxial region. The first and second wells may form respective innermost junctions (e.g., the junctions 121A, 121B, 221A, 221B, 321A, 321B of FIGS. 1-3) with a JFET neck region (e.g., the JFET neck region 103, 203, 303 of FIGS. 1-3). The JFET neck region extends between the innermost junctions.

At operation 504, a germanium layer (e.g., the germanium layers 116, 216, 316 of FIGS. 1-3) may be formed (e.g., implanted) within the epitaxial region adjacent the top. The germanium layer may extend continuously between the sides (e.g., as shown in FIGS. 1 and 2), may extend continuously across the JFET neck region and between the respective innermost junctions of the wells and the JFET neck region (e.g., as shown in FIG. 3), or otherwise along the top within the scope of the present examples.

Formation of the germanium layer between the respective innermost junctions of the wells and the JFET neck region or with any other width that does not completely span the device, may include placing a mask (e.g., the mask 417 of FIG. 4) across the top of the epitaxial layer, forming the germanium layer through a gap (e.g., the gap 419 of FIG. 4) of the mask, and removing the mask, as described in greater detail above in connection with FIG. 4.

At operation 506, a gate (e.g., the gates 112, 212, 312 of FIGS. 1-3) is formed adjacent the top. The gate comprises a gate dielectric (e.g., the gate dielectrics 114, 214, 314 of FIGS. 1-3), a doped gate material (e.g., the doped gate materials 113, 213, 313 of FIGS. 1-3), and a gate contact (e.g., the gate contacts 122, 222, 322 of FIGS. 1-3). In various examples, the gate dielectric may have a uniform thickness (e.g., as shown in FIG. 1) or may include a central thickened dielectric portion (e.g., the thickened dielectric portions 215, 315 of FIGS. 2 and 3). The gate dielectric may be formed across the top.

An oxidation process may be performed. The oxidation process may include exposing silicon particles of the epitaxial region and germanium particles of the germanium layer to oxygen, thereby forming SiO2 and GeO2 particles, respectively. The SiO2 and GeO2 particles may collectively form the gate dielectric.

When the gate dielectric has the uniform thickness and the germanium layer extends continuously between the sides of the epitaxial region (e.g., as shown in FIG. 1), an oxidation time for forming the gate dielectric may be reduced (e.g., compared to forming a gate dielectric in the absence of the germanium layer), thereby reducing a manufacturing time for forming the example MOSFET.

When the gate dielectric includes the central thickened dielectric portion and the germanium layer extends continuously between the sides of the epitaxial region (e.g., as shown in FIG. 2), the gate dielectric may initially be formed using an oxidation process that takes an amount of time typically taken to form the gate dielectric in the absence of a germanium layer. The gate dielectric may initially have a thickness (e.g., along the y axis) equal to or greater than a thickness of the central thickened dielectric portion. Excess portions of the gate dielectric (e.g., on either side of the central thickened dielectric portion) may be removed (e.g., by etching) to form the central thickened dielectric portion. The thickened portion of the gate dielectric may be aligned axially with the JFET neck region.

When the gate dielectric includes the central thickened dielectric portion and the germanium layer extends continuously between the respective innermost junctions of the wells and the JFET neck region (e.g., as shown in FIG. 3), the gate dielectric may be formed using an oxidation process that takes an amount of time typically taken to form the gate dielectric in the absence of a germanium layer. Oxidation of germanium particles of the germanium layer and silicon particles of the epitaxial layer may cause the thickened portion to be formed thicker than remaining outer portions of the gate dielectric (e.g., where the germanium layer is not present beneath the gate dielectric). Accordingly, etching may not be required to form the central thickened dielectric portion.

The method may further include placing various contacts (e.g. the drain contacts 118, 218, 318, the source contacts 120A, 120B, 220A, 220B, 320A, 320B, and the gate contacts 122, 222, 322 of FIGS. 1-3).

### Feature Combinations

In accordance with various examples of the present disclosure, a MOSFET may comprise an epitaxial region, a JFET neck region of the epitaxial region, a gate, and a germanium layer of the epitaxial region. The epitaxial region may include a top, an opposite bottom spaced vertically from the top, a first side, and a laterally opposite second side spaced from the first side. The JFET neck region may be between the first and second sides. The gate may be adjacent the top. The JFET neck region may underlie at least a portion of the gate. The germanium layer may be adjacent the top and may underlie at least a portion of the gate.

In accordance with various examples of the present disclosure, a MOSFET may comprise an epitaxial region, a JFET neck region of the epitaxial region, a gate, and a germanium layer of the epitaxial region. The epitaxial region may include a top, an opposite bottom spaced vertically from the top, a first side, and a laterally opposite second side spaced from the first side. The JFET neck region may be between the first and second sides. The gate may be adjacent the top. The gate may include a gate dielectric. The gate dielectric may include a central thickened dielectric portion having a greater thickness than outer remaining portions of the gate dielectric. The JFET neck region may underlie the central thickened dielectric portion. The germanium layer may be adjacent the top and may extend laterally across an upper portion of the JFET neck region.

In accordance with various examples of the present disclosure, a method of making a MOSFET using an epitaxial region on a drain substrate may be provided. The volume of semiconductor material may include a top, an opposite bottom spaced vertically from the top, a first side, a laterally opposite second side spaced from the first side, and a JFET neck region adjacent the top between the first and second sides. The method may comprise: forming laterally spaced first and second wells of the epitaxial region adjacent the top, the first and second wells forming respective innermost junctions with the JFET neck region, the JFET neck region extending between the respective innermost junctions; forming a germanium layer of the epitaxial region adjacent the top, the germanium layer extending continuously between the respective innermost junctions; and forming a gate adjacent the top, the gate comprising a gate dielectric.

In various examples of the present disclosure, a MOSFET may comprise laterally spaced apart first and second wells of an epitaxial region. The first and second wells may form respective innermost junctions with a JFET neck region. A germanium layer may extend continuously between the respective innermost junctions.

In combination with any of the previous examples, a gate may comprise a gate dielectric. The gate dielectric may include a central thickened dielectric portion having a greater thickness than outer remaining portions of the gate dielectric. A JFET neck region and a germanium layer may both underlie the central thickened dielectric portion.

In combination with any of the previous examples, a gate may comprise a doped gate material. A gate dielectric may underlie the doped gate material. The doped gate material may present a recess. The central thickened dielectric portion may be at least partly in the recess.

In combination with any of the previous examples, a germanium layer may extend continuously between first and second sides of an epitaxial layer.

In combination with any of the previous examples, a gate dielectric may have a uniform thickness.

In combination with any of the previous examples, an epitaxial region may comprise silicon carbide. A gate dielectric may comprise germanium dioxide and silicon carbide.

In combination with any of the previous examples, a method may comprise: etching respective portions of a gate dielectric to form a central thickened dielectric portion having a greater thickness than outer remaining portions of the gate dielectric. A JFET neck region may underlie the central thickened dielectric portion.

In combination with any of the previous examples, formation of a germanium layer may include: placing a mask across a top of an epitaxial region, the mask defining a gap, a JFET neck region underlying the gap; and depositing the germanium layer through the gap.

### General Considerations

While the present disclosure has been described herein with respect to certain illustrated examples, those of ordinary skill in the art will recognize and appreciate that the present disclosure is not so limited. Rather, many additions, deletions, and modifications to the illustrated and described examples may be made without departing from the scope of the disclosure as hereinafter claimed along with their legal equivalents. In addition, features from one example may be combined with features of another example while still being encompassed within the scope of the disclosure as contemplated by the inventors.

For example, although described herein with regard or in relation to one or more particular kinds of electronic devices (e.g., MOSFET), the technology may be more broadly applicable to one or more other kinds of electronic devices as well. Further, one with ordinary skill in the art will recognize that the technology described herein may, when applicable, be implemented in enhancement mode or depletion mode. Additionally, the technology described herein may, when applicable, be implemented as an N-channel or P-channel device, wherein, in general, regions that are N-doped or P-doped in N-channel implementations may be, respectively, P-doped or N-doped in P-channel implementations. Additionally, the various example materials identified herein may, in some aspects, be replaced or supplemented with substantially any other suitable material. For example, gate material may include polysilicon, a metal or alloy of metals, or other suitable material; gate oxide or dielectric may include silicon dioxide, aluminum dioxide, hafnium dioxide, germanium dioxide, silicon nitride, or other suitable material; and semiconductor material may include silicon carbide, gallium nitride, zinc oxide, or other suitable material.

Additionally, in general, unless otherwise specified or unless one with ordinary skill in the art would understand otherwise, doping concentrations (measured in parts per cubic centimeter) for contact implants may be approximately between 10\hat{ }18 and 10\hat{ }22; doping concentrations for channel and threshold forming implants may be approximately between 10\hat{ }16 and 10\hat{ }17; doping concentrations for shielding implants may be approximately between 10\hat{ }17 and 10\hat{ }19; and doping concentrations for conductivity improvement implants (e.g., N-doping in the junction field-effect transistor neck region) may be approximately between 10\hat{ }16 and 10\hat{ }17. Relatedly, a structure or region may contain two or more different doping doses. For example, one with ordinary skill in the art will recognize that some P-wells may contain a lower dose P-well portion and a higher dose unclamped inductive switching portion.

In this description, references to “one embodiment”, “an embodiment”, “embodiments”, “an example”, “one example”, or “examples” mean that the feature or features being referred to are included in at least one embodiment or example of the technology. Separate references to “one embodiment”, “an embodiment”, “embodiments”, “an example”, “one example”, or “examples” in this description do not necessarily refer to the same embodiment or example and are also not mutually exclusive unless so stated and/or except as will be readily apparent to those skilled in the art from the description. For example, a feature, structure, act, etc. described in one embodiment may also be included in other embodiments but is not necessarily included. Thus, the current technology can include a variety of combinations and/or integrations of the embodiments described herein.

Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter herein, unless otherwise expressly stated and/or readily apparent to those skilled in the art from the description.

As used herein, the terms “comprises,” “comprising,” “includes,” “including,” “has,” “having” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus. Further, unless expressly stated to the contrary, “or” refers to an inclusive or and not to an exclusive or. For example, a condition A or B is satisfied by any one of the following: A is true (or present) and B is false (or not present), A is false (or not present) and B is true (or present), and both A and B are true (or present).

The patent claims at the end of this patent application are not intended to be construed under 35 U.S.C. § 112(f) unless traditional means-plus-function language is expressly recited, such as “means for” or “step for” language being explicitly recited in the claim(s).

What is claimed is:

1. A metal-oxide semiconductor field-effect transistor (MOSFET), comprising:
an epitaxial region including a top, an opposite bottom spaced vertically from the top, a first side, and a laterally opposite second side spaced from the first side;
a junction field-effect transistor (JFET) neck region of the epitaxial region located between the first and second sides;
a gate adjacent the top, the JFET neck region underlying at least a portion of the gate; and
a germanium layer of the epitaxial region adjacent the top and underlying at least the portion of the gate.

2. The MOSFET of claim 1, comprising:
laterally spaced apart first and second wells of the epitaxial region, the first and second wells forming respective innermost junctions with the JFET neck region,
the germanium layer extending continuously between the respective innermost junctions.

3. The MOSFET of claim 2,
the gate comprising a gate dielectric,
the gate dielectric including a central thickened dielectric portion having a greater thickness than outer remaining portions of the gate dielectric, the JFET neck region and the germanium layer both underlying the central thickened dielectric portion.

4. The MOSFET of claim 3,
the gate comprising a doped gate material, the gate dielectric underlying the doped gate material and the doped gate material presenting a recess, the central thickened dielectric portion being at least partly in the recess.

5. The MOSFET of claim 1,
the germanium layer extending continuously between the first and second sides.

6. The MOSFET of claim 5,
the gate dielectric having a uniform thickness.

7. The MOSFET of claim 5,
the gate dielectric including a central thickened dielectric portion having a greater thickness than outer remaining portions of the gate dielectric, the JFET neck region underlying the central thickened dielectric portion.

8. The MOSFET of claim 1,
the epitaxial region comprising silicon carbide,
the gate dielectric comprising germanium dioxide and silicon dioxide.

9. A metal-oxide semiconductor field-effect transistor (MOSFET), comprising:
an epitaxial region including a top, an opposite bottom spaced vertically from the top, a first side, and a laterally opposite second side spaced from the first side;
a junction field-effect transistor (JFET) neck region of the epitaxial region located between the first and second sides;
a gate located adjacent the top, the gate comprising a gate dielectric including a central thickened dielectric portion having a greater thickness than outer remaining portions of the gate dielectric, the JFET neck region underlying the central thickened dielectric portion; and
a germanium layer of the epitaxial region adjacent the top and extending laterally across an upper portion of the JFET neck region.

10. The MOSFET of claim 9,
the germanium layer extending continuously between the first and second sides.

11. The MOSFET of claim 9,
the gate comprising a doped gate material, the gate dielectric underlying the doped gate material, the doped gate material presenting a recess, and the central thickened dielectric portion being at least partly in the recess.

12. The MOSFET of claim 9,
the epitaxial region comprising silicon carbide,
the gate dielectric comprising germanium dioxide and silicon dioxide.

13. A method of making a metal-oxide semiconductor field-effect transistor (MOSFET) using an epitaxial region on a drain substrate, the epitaxial region including a top, an opposite bottom spaced vertically from the top, a first side, a laterally opposite second side spaced from the first side, and a junction field-effect transistor (JFET) neck region adjacent the top between the first and second sides, the method comprising:
forming laterally spaced first and second wells of the epitaxial region adjacent the top, the first and second wells forming respective innermost junctions with the JFET neck region, the JFET neck region extending between the respective innermost junctions;
forming a germanium layer of the epitaxial region adjacent the top, the germanium layer extending continuously between the respective innermost junctions; and
forming a gate adjacent the top, the gate comprising a gate dielectric.

14. The method of claim 13,
the germanium layer extending continuously between the first and second sides.

15. The method of claim 14,
the gate dielectric having a uniform thickness.

16. The method of claim 14, comprising:
etching respective portions of the gate dielectric to form a central thickened dielectric portion having a greater thickness than outer remaining portions of the gate dielectric, the JFET neck region underlying the central thickened dielectric portion.

17. The method of claim 16,
the gate comprising a doped gate material, the gate dielectric underlying the doped gate material, the doped gate material presenting a recess, the central thickened dielectric portion being at least partly in the recess.

18. The method of claim 13, the formation of the germanium layer including—placing a mask across the top of the epitaxial region, the mask defining a gap, the JFET neck region underlying the gap; and
depositing the germanium layer through the gap.

19. The method of claim 18,
the gate dielectric comprising a central thickened dielectric portion having a greater thickness than outer remaining portions of the gate dielectric, the JFET neck region and the germanium layer both underlying the central thickened dielectric portion.

20. The method of claim 13,
the epitaxial region comprising silicon carbide,
the gate dielectric comprising germanium dioxide and silicon dioxide.
